(19) United States
(12) Patent Application Publication
(10) Pub. No.: US 2024/0166818 A1
(43) Pub. Date: May 23, 2024

(54) POLYIMIDES HAVING LOW DIELECTRIC LOSS

(71) Applicant: SOLVAY SPECIALTY POLYMERS ITALY S.P.A., Bollate (Milano) (IT)

(72) Inventors: Dipankar Basak, Vadodara (IN); Chinmay Nardele, Vadodara (IN); Rahul Shingte, Vadodara (IN); Mattia Bassi, Milano (IT)

(73) Assignee: SOLVAY SPECIALTY POLYMERS ITALY S.P.A., Bollate (Milano) (IT)

(21) Appl. No.: 18/546,729

(22) PCT Filed: Feb. 11, 2022
(86) PCT No.: PCT/EP2022/053319

§ 371 Date: Aug. 16, 2023

(30) Foreign Application Priority Data
Feb. 16, 2021 (IN) 202121006450
Mar. 25, 2021 (EP) 21165039.5
Sep. 16, 2021 (IN) 202121041899

(51) Int. Cl. C08G 73/12; G03F 7/023

(52) U.S. Cl. CPC C08G 73/12; G03F 7/023

(57) ABSTRACT

The present invention relates to novel polyimide polymers containing certain fluorinated diamine moieties, said polyimide polymers being characterized by excellent dielectric performances. The present invention also relates to the use of said polyimide-based polymers in polymer compositions in microelectronics applications.

This application claims priority from Indian patent application Nr 202121006450 filed on 16 Feb. 2021, European patent application Nr 21165039.5 filed on 25 Mar. 2021, and Indian patent application Nr 202121041899 filed on 16 Sep. 2021, the whole content of each of these applications being incorporated herein by reference for all purposes.

### TECHNICAL FIELD

The present invention relates to polyimide polymers containing certain fluorinated diamine moieties, said polyimide polymers being characterized by excellent dielectric performances, in particular low dielectric loss (Df). The present invention also relates to the use of said polyimide polymers in microelectronics applications.

### BACKGROUND ART

Polyimides are widely used in microelectronics due to their excellent heat resistance, mechanical properties and excellent solvent resistance and radiation resistance. However, their dielectric properties are relatively high: dielectric constant is about 3.4, and dielectric loss factor is 0.005˜0.010). To a certain extent, those values limit their application in different fields.

Therefore, the development of polyimide materials with excellent heat resistance, low dielectric constant and low dielectric loss is of great significance.

Several approaches can be found in the literature to reduce the dielectric constant of polyimide materials. Among those, introducing fluorine and free volumes in the material are methods known in the art to enhance dielectric properties. In particular, fluorine is widely utilized for reducing dielectric constant of materials because it can reduce the strength of dipoles.

For instance, CN10669336 discloses fluorine-containing polyimide resin composition formed by polymerization of fluorine-containing dianhydride (4,4′-(hexafluoroisopropylidene)diphthalic anhydride, hereinafter “6-FDA”) and fluorine-containing diamine (2,2-bis(4-aminophenyl) hexafluoropropane, hereinafter “BPAFDA”), as a matrix, and uses low molecular weight polyphenyl ether with a low dielectric constant and polytetrafluoroethylene as filling modifier.

Other methods for reducing the dielectric properties of polyimides are through pyrolysis, photolysis, solvent method or introduction of microporous materials, to increase the air content, thereby reducing the dielectric constant.

CN109535713 discloses composite materials comprising glass hollow microspheres coated with a polyimide material formed by reaction of 6-FDA and 2,2′-bis(trifluoromethyl)-4,4′-diaminobiphenyl (“TFMB”, hereinafter).

Being insoluble in most common solvents, polyimides are usually processed in the form of their precursor poly(amic acids), which are then thermally converted to the imide structure by thermal imidization.

Polyimides are widely used in the semiconductor industry for passivation films, stress buffer films, particle shielding films, dry etching masks, micro-electromechanical systems, interlayer insulating films and the like. Polyimide materials are often used as a protective coating for integrated circuit devices since polyimide can pass the reliability test for integrated circuit devices. In addition, polyimide plays a key role in electronic packaging, enameled wires, printed circuit boards, sensing elements, separation membranes and structural materials.

It would be advantageous to have polyimide polymers having improved dielectric performances while possessing appropriate solubility and low water absorption.

It has now been found that polyimide polymers comprising recurring units deriving from certain fluorinated diamines have dielectric properties, mechanical properties and water uptake characteristics that can be conveniently modulated to suit the needs of the microelectronic industry.

### SUMMARY OF INVENTION

An object of the present invention is a polyamic acid polymer, [polymer (PAA)], obtained by polymerizing:
an aromatic carboxylic acid component [component (AC)];
a diamine component [diamine (D)], wherein the diamine component is an organic fluorinated diamine of formula (I):

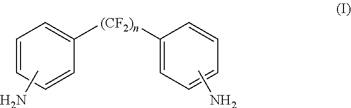

with n being an integer from 2 to 10, and
optionally, a diamine component [diamine (D1)] different from diamine (D).

Component (AC) preferably comprises an aromatic tetracarboxylic anhydride.

Part or all of the amic acid groups in polyamic acid polymer, polymer (PAA), may be in the form of an ester. Accordingly the expression “polymer (PAA)” is used in the remainder of the present specification to refer to polyamic acid polymers in which part or all of the amic acid groups are in the form of an ester.

In a further object, the present invention provides a polyimide polymer [polymer (PI)] obtainable from polymer (PAA).

The expression “polyimide polymer (PI/PAA)” will be used in the remainder of the present specification to refer to at least one compound selected from the group consisting of polyimide polymer [polymer (PI)] and polyamic acid polymer [polymer (PAA)].

The polyimide polymer (PI/PAA) of the present invention is useful as material for the production of printed circuit boards, flexible printed circuit boards, as well as copper clad laminates and the like.

Since the polyimide polymer (PI/PAA) dissolves very well in various solvents, it can be suitably used in photo-patterning procedures involving positive or negative development.

Accordingly another object of the invention is a photosensitive polymer composition comprising:
a polyimide polymer (PI/PAA) as defined above; and
a photosensitive agent.

The photosensitive polymer composition of the present invention is useful as material for the production of printed circuit boards by a method comprising the steps of exposing a layer of the composition selectively to actinic radiation through a photomask having a pattern and developing the exposed or unexposed part of the layer.

Another object of the present invention is thus a method for forming a pattern in a layer applied on a substrate, said method comprising:
a) applying a coating of the photosensitive polymer composition on a substrate;
b) masking the applied coating with a photomask having a pattern;
c) exposing the masked substrate to a source of actinic radiation and developing the photosensitive film; and
d) heat curing the developed substrate to form a polyimide pattern.

The present invention further provides for a solution comprising at least one compound selected from the group consisting of polyimide polymer (PI) and polyamic acid polymer (PAA).

### DESCRIPTION OF EMBODIMENTS

In the context of the present invention, the use of parentheses “( . . . )” before and after symbols or numbers identifying formulae or parts of formulae has the mere purpose of better distinguishing that symbol or number with respect to the rest of the text; thus, said parentheses could also be omitted.

The term “film”, as used herein, is intended to mean a free-standing film or self-supporting or non-self-supporting coating.

The term “polyimide precursor” as used herein is intended to include any polyimide precursor material derived from a combination of certain carboxylic acid compound and diamine and capable of conversion to polyimide.

A first object of the invention is a polyamic acid polymer [polymer (PAA)] which is obtained by the polymerization of:
an aromatic carboxylic acid component [component (AC)],
a diamine component [diamine (D)] wherein the diamine component is an organic fluorinated diamine of formula (I):

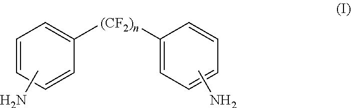

with n being an integer from 2 to 10, and
optionally, a diamine component [diamine (D1)] different from diamine (D).

Polymer (PAA) is a polyamic acid precursor to a polyimide polymer.

Component (AC) may comprise an aromatic tetracarboxylic anhydride. Any aromatic tetracarboxylic anhydride may be used for preparing polymer (PAA).

The aromatic tetracarboxylic anhydride for preparing polymer (PAA) may be selected from the group consisting of pyromellitic dianhydride (PMDA), 3,3′,4,4′-biphenyl tetracarboxylic dianhydride (BPDA), 4,4′-oxydiphthalic anhydride (ODPA), isomeric diphenyl sulfide dianhydride (TDPA), triphenyl diether dianhydride (HQDPA), 3,3′,4,4′-benzophenone tetracarboxylic dianhydride (BTDA), 4,4′-bisphenol A dianhydride (BPADA), 3,3′,4,4′-diphenyl sulfone tetracarboxylic dianhydride (DSDA), 4,4′-(hexafluoroisopropylidene)diphthalic anhydride (6-FDA), 9,9-bis (trifluoromethyl)xanthene tetracarboxylic dianhydride (6FCDA), 1,4-bis(trifluoromethyl)-2,3,5,6 pyromellitic dianhydride (P6FDA), 1,4-bis(3,4-dicarboxy-trifluorophenoxy)tetrafluorobenzene dianhydride (10-FEDA), 2,2-bis[4-(3,4- dicarboxy phenoxy) phenyl] hexafluoropropane dianhydride (BFDA) or 1,4-difluoro pyromellitic dianhydride (PF2DA).

The aromatic tetracarboxylic anhydride may advantageously be selected from the group consisting of pyromellitic dianhydride (PMDA), 4,4′-oxydiphthalic anhydride (ODPA), 4,4′-(hexafluoroisopropylidene)diphthalic anhydride (6-FDA) and 3,3′, 4,4′-biphenyl tetracarboxylic dianhydride (BPDA).

In an embodiment of the invention, component (AC) is a C₁-C₂₀ ester of an aromatic carboxylic acid further comprising carboxylic acid groups which is suitable to form an imide upon reaction with an amine. In a preferred aspect of said embodiment, the carboxylic acid ester group comprises polymerizable side chains.

Polymer (PAA) may be obtained by the polymerization of a component (AC) which is an aromatic tetracarboxylic acid compound selected from those of formula (V):

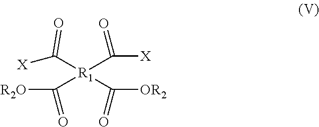

wherein R₁ is an aromatic tetravalent group, which may comprise one or more than one aromatic ring, which may be optionally fused together, R₂ is a C₁-C₂₀ alkyl radical, optionally comprising at least one polymerizable group, and X is OH, Cl, Br, I, preferably OH or Cl.

Component (AC) may consist of an aromatic tetracarboxylic acid compound of formula (V). In such an instance polymer (PAA) will comprise, essentially consist of or consist of amic acid groups in the form of esters. Component (AC) may alternatively comprise an aromatic tetracarboxylic anhydride and an aromatic tetracarboxylic acid compound selected from those of formula (V). In such a case a part of the amic acid groups in polymer (PAA) will be in the form of an ester.

In formula (V), R₁ may be selected from the group consisting of:

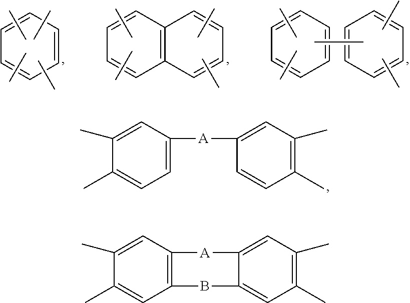

with A being selected from the group consisting of —O—, —C(O)—, —S—, —SO₂—, —SO—, —(CH₂)ₗ— with l an integer from 1 to 6, —C(CH₃)₂—, —C(CF₃)₂—, —(CF₂)ₘ— with m an integer from 1 to 6, cycloalkylenes having 4 to 8 carbon atoms; alkylidenes having 1 to 6 carbon atoms; cycloalkylidenes having 4 to 8 carbon atoms; and B, the same or different from A, being selected from the group consisting of —O—, —C(O)—, —S—, —SO₂—, —SO—, —(CH₂)ₗ— with l an integer from 1 to 6, —C(CH₃)₂—, —C(CF₃)₂—, —(CF₂)ₘ— with m an integer from 1 to 6.

In formula (V), R₂ is a C₁-C₂₀ alkyl radical. In an embodiment of the invention R₂ is a C₁-C_{8,} preferably a C₁-C₄ alkyl radical, e.g. methyl, ethyl, propyl, butyl radical. In an alternative embodiment of the invention R₂ is selected from C₄-C₂₀ alkyl radicals comprising at least one polymerizable group. The polymerizable group may be selected from:

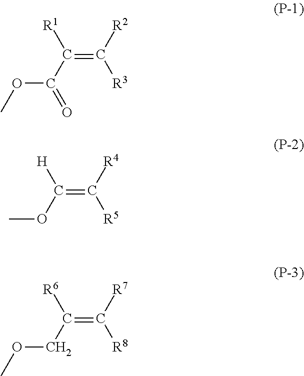

wherein, in formulas (P-1) to (P-3), R1, R2, R3, R4, R5, R6, R7 and R8 are independently hydrogen, methyl, or ethyl; in formula (P-2), at least one of R4 and R5 is methyl or ethyl. Preferably R₂ is selected from C₄-C₂₀ alkyl radicals comprising at least on polymerizable group of formula (P-1). Advantageously, R₂ may be —(CH₂)ₚ—O—C(O)C(R*)═CH₂, where R* is H or a C₁-C₅ alkyl, and p is an integer from 1 to 5; preferably R₂ is —(CH₂)ₚ—O—C(O)C(CH₃)═CH₂, with p equal to 1 or 2.

A non-limiting example of a compound of formula (V) suitable for use in the preparation of polymer (PAA) is:

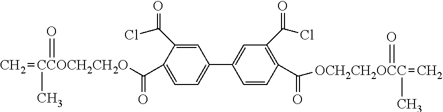

hereinafter referred to as HEMA2-BPDA.

One or more than one aromatic tetracarboxylic anhydride and/or compound of formula (V) can be used in the preparation of polymer (PAA) in combination with diamine (D) and optionally diamine (D1).

Diamine (D) is an organic fluorinated diamine of formula (I). In formula (I), n may be any integer from 2 to 8, from 2 to 6, more preferably from 4 to 6.

Diamine (D) is preferably selected from diamines of formula (II), (Ill) or (IV):

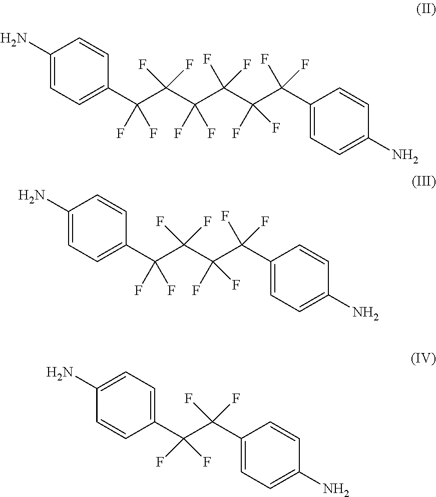 [SMILES: Nc1ccc(C(F)(F)C(F)(F)C(F)(F)C(F)(F)C(F)(F)C(F)(F)c2ccc(N)cc2)cc1 ; Nc1ccc(C(F)(F)C(F)(F)C(F)(F)C(F)(F)c2ccc(N)cc2)cc1 ; Nc1ccc(C(F)(F)C(F)(F)c2ccc(N)cc2)cc1]

The amount of diamine (D) in polymer (PAA) may range from 100.0 mol % to 0.1 mol % with respect to the total amount of moles of diamine units in the polymer.

In a first embodiment diamine (D) is the sole diamine in polyamic acid polymer (PAA), that is diamine (D) represents 100.0 mol % of the total amount of moles of diamine units in the polymer.

In such an embodiment polymer (PAA) typically consists of recurring units deriving from diamine (D) and at least one aromatic tetracarboxylic anhydride as above detailed.

In an aspect of said embodiment, polymer (PAA) is obtained by polymerizing:
a) a component (AC) selected from the group consisting of pyromellitic dianhydride (PMDA), 4,4′-oxydiphthalic anhydride (ODPA), 3,3′,4,4′-biphenyl tetracarboxylic dianhydride (BPDA), 4,4′-(hexafluoroisopropylidene)diphthalic anhydride (6-FDA) and a compound of formula (V), and
b) a diamine (D) of formula (I)

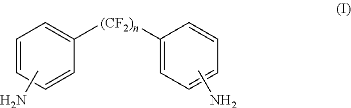

with n being an integer from 2 to 10, 2 to 6, preferably an integer from 4 to 6.

In a preferred aspect of said embodiment, polymer (PAA) is obtained by polymerizing a component (AC) selected from the group consisting of 4,4′-oxydiphthalic anhydride (ODPA), 3,3′,4,4′-biphenyl tetracarboxylic dianhydride (BPDA), 4,4′-(hexafluoroisopropylidene)diphthalic anhydride (6-FDA) and a compound of formula (V) wherein R₂ is —(CH₂)ₚ—O—C(O)C(R*)═CH₂, with a diamine (D) selected from those of formulae (II), (III) and (IV):

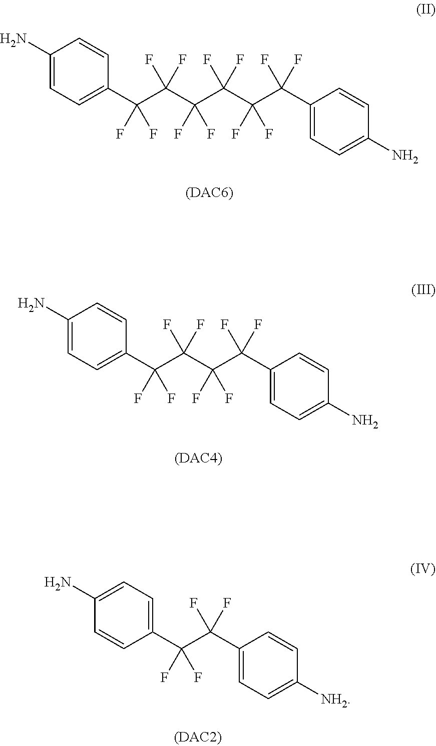 [SMILES: Nc1ccc(C(F)(F)C(F)(F)C(F)(F)C(F)(F)C(F)(F)C(F)(F)c2ccc(N)cc2)cc1 ; Nc1ccc(C(F)(F)C(F)(F)C(F)(F)C(F)(F)c2ccc(N)cc2)cc1 ; Nc1ccc(C(F)(F)C(F)(F)c2ccc(N)cc2)cc1]

Polymer (PAA) may optionally comprise a further diamine (D1) different from the diamine (D) of formula (I). In such an embodiment, polymer (PAA) comprises diamine (D) and at least one diamine (D1). The amount of diamine (D) may range from 99.9 to 0.1 mol % of the total amount of moles of diamine units in the polymer.

Advantageously, the amount of diamine (D) may be 95.0 to 5.0 mol %, 90.0 to 10.0 mol %, 75.0 to 10.0 mol %, 75.0 to 12.0 mol % of the total amount of moles of diamine units in the polymer (PAA).

Suitable diamines (D1) that can be used in preparing polymer (PAA) are selected from the group consisting of 4,4′-diaminodiphenyl ether (ODA), p-phenylenediamine, (PDA), 3,3′-Diamino -5,5′-bis (trifluoromethyl) biphenyl (TFMB), m-phenylenediamine, diphenyl dimethyl methane diamine (DMMDA), 1,3-bis (3-aminophenoxy) benzene (BAPB), 4,4′-bisphenol A ether diamine (BAPP), 4,4′-bis (4-aminophenoxy) diphenylsulfone (BAPS), 4,4′-bis (4-aminophenoxy) diphenyl ether (BAPE), diamino diphenyl (methyl) ketone (DABP), 4,4′-diamino-triphenylamine (DATPA), 4,4′-diaminodiphenyl methane (MDA), diaminodiphenyl sulfone (DDS), 3,4′-diaminodiphenyl ether (3,4′-ODA), 3,3′-dimethyl-4,4′-diamino diphenyl methane (MDI), 4,4′-diamino-diphenoxy-1″,4″-benzene, 4,4′-diamino-diphenoxy-1″,3″-benzene, 3,3′-diamino-diphenoxy-1″,3″-benzene, 4,4′-diamino-diphenyl-4″,4-phenyl-isopropyl propane, perfluorinated isopropylidene diamine (4-BDAF), 2,2-bis (4-aminophenyl) hexafluoropropane (6FDAM), 1,4-bis-(4-amino-2-trifluoromethylphenoxy) benzene (6FAPB), 2,5-bis(4-amino-2-trifluoromethyl-phenoxy)-tert benzene (DNTBHQ-2TF), 4,4′-bis (4-amino-2-trifluoromethyl-phenoxy)-biphenyl (DNBP-2TF), 5-trifluoromethyl-1,3-diaminobenzene (TFMB), 5-trifluoromethoxy-1,3-diaminobenzene (TFMOB), 1,4-diamino-2,3,5,6-tetrafluoro-benzene (4FPPD), 4,4′-diamino octafluoro biphenyl (8FZB), 4,4′-diamino diphenyl ether octafluoro (8FODB), bis (3-amino-phenyl)-4-(trifluoromethyl) phenyl phosphine oxide (m-DA6FPPO), or 2,2-bis(4-aminophenyl)hexafluoropropane (BPAFDA), bis(4-aminophenoxy)hexafluorocyclobutane (DPFCB-N, hereinafter).

Advantageously polymer (PAA) may be obtained by polymerizing:
a) a component (AC),
b) 5.0 to 95.0 mol %, 15.0 to 85.0 mol %, even 20.0 to 80.0 mol % of diamine (D), and
c) 5.0 to 95.0 mol %, 15.0 to 85.0 mol %, even 20.0 to 80.0 mol % of diamine (D1).

The molar percentages of diamine (D) and diamine (D1) are expressed with respect to the total amount of moles of diamine units (diamine (D)+diamine (D1)) in the polymer.

Polymer (PAA) may conveniently be obtained by polymerizing:
a) a component (AC) selected from the group consisting of pyromellitic dianhydride (PMDA), 4,4′-oxydiphthalic anhydride (ODPA), 3,3′,4,4′-biphenyl tetracarboxylic dianhydride (BPDA), 4,4′-(hexafluoroisopropylidene)diphthalic anhydride (6-FDA) and a compound of formula (IV),
b) 5.0 to 95.0 mol %, 15.0 to 85.0 mol %, even 20.0 to 80.0 mol %, of the total amount of moles of diamine units in the polymer, of a diamine (D) selected from those of formulae (II) and (III) as detailed above, and
c) 5.0 to 95.0 mol %, 15.0 to 85.0 mol %, even 20.0 to 80.0 mol %, of diamine (D1) selected from 4,4′-diaminodiphenyl ether (ODA), p-phenylenediamine, (PDA), bis(4-aminophenoxy)hexafluorocyclobutane (DPFCB-N).

Polymers (PAA), precursors to polyimide polymers (PI) with advantageous properties, may obtained by polymerizing:
a) a component (AC) selected from 4,4′-oxydiphthalic anhydride (ODPA), 3,3′, 4,4′-biphenyl tetracarboxylic dianhydride (BPDA) and HEMA2-BPDA,
b) 5.0 to 95.0 mol %, 15.0 to 85.0 mol %, even 20.0 to 80.0 mol % of diamine (D) of formula (II), (DAC6), and
c) 5.0 to 95.0 mol %, 15.0 to 85.0 mol %, even 20.0 to 80.0 mol % of diamine (D1) selected from 4,4′-diaminodiphenyl ether (ODA) and p-phenylenediamine, (PDA).

Polymer (PAA) of the present invention can be obtained by any known method, and is not limited to a particular production method.

The polymerization of the anhydride component with diamine (D) and optionally diamine (D1) is suitably carried out at a temperature of −20 to 150° C., preferably −5 to 100° C. Polymerization is typically carried out in a polar solvent. Suitable solvents are N,N-dimethylformamide, N,N-dimethylacetamide, N-methylpyrrolidone, N-vinylpyrrolidone, N-methylcaprolactam, dimethylsulfoxide, tetramethylurea, pyridine, dimethylsulfone, hexamethylsulfoxide, m-cresol, γ-butyrolactone and mixtures thereof. The result is a polyamic acid polymer, precursor to a polyimide polymer, in the form of a solution in said solvent.

In this specification, a solution containing a polyamic acid and an organic solvent is meant to be a “polyamic acid solution”. In a case where the polyamic acid is obtained by the above described method, a reaction solution as obtained at the end of the polymerization process is sometimes referred to as “polyamic acid solution”.

In performing the polymerization reaction of the polyamic acid, a solution viscosity may be properly chosen depending upon a purpose of the use (coating, casting, etc.) or a purpose of the production. From the viewpoint of workability, it is desirable that the polyamic acid solution (polyimide precursor solution) has a rotational viscosity, as measured at 30° C., of from about 0.01 to 900 Pa·s, preferably from 0.01 to 400 Pa·s, and more preferably from 0.02 to 400 Pa·s. In consequence, it is preferable that the polymerization reaction is carried out to an extent that the formed polyamic acid exhibits the foregoing viscosity.

The polyamic acid polymer (PAA) can be isolated in the form of powder by precipitating the same with water from the polyamic acid solution as above defined and drying.

The polyamic acid polymer solution as above defined can also be used as such in the preparation of an article or it can be converted into a polyimide polymer [polymer (PI)].

Accordingly, in a further object, the present invention provides a polyimide polymer (PI) obtainable from polymer (PAA).

Polymer (PI) of the present invention can be obtained by dehydrating and ring closing the polymer (PAA) by any known method, and is not limited to a particular production method.

According to one embodiment of the present invention, polyamic acid polymer (PAA) is imidized in order to obtain a polyimide polymer (PI) by cyclodehydration of the polyamic acid. The cyclodehydration can be carried out with an azeotropic method using an azeotropic solvent, with a thermal method, or with a chemical method. The imidization from polyamic acid to polyimide can be carried out with any ratio between 1% and 100%. That is, it is possible to synthesize a polyamic acid which is partially imidized.

The cyclodehydration can be carried out by a thermal method, thus by heating polymer (PAA). The method for heating polymer (PAA) is not limited to a particular one, and can be, for example, a method in which the polyamic acid solution is cast or applied to a support such as a glass plate, a metal plate, or PET (polyethylene terephthalate), and then it is heat treated at a temperature in a range between 80° C. and 500° C. A film of polyimide polymer (PI) can thus be obtained by this method.

Alternatively, the cyclodehydration of polymer (PAA) can be carried out by an azeotropic method, including adding an azeotropic solvent and drying the polyamic acid solution with heat under reduced pressure. In general, it is preferable that heating is carried out for a time in a range between 1 minute and 5 hours.

Alternatively, in order to reduce heating time and to obtain a polyimide having certain improved characteristics, a polyamic acid solution can be imidized by a chemical method including the addition of an imidizing agent and/or a dehydrating catalyst followed by heating with the azeotropic method as above described.

The imidizing agent is not limited to a particular one and can be tertiary amine. The tertiary amine is further preferably a heterocyclic tertiary amine. Suitable examples of the heterocyclic tertiary amine preferably encompass pyridine, picoline, quinoline, and isoquinoline. Suitable examples of the dehydrating catalyst preferably encompass acetic anhydride, propionic anhydride, n-butyric anhydride, benzoic anhydride, and trifluoroacetic anhydride.

When adding the imidizing agent and/or the dehydrating catalyst to the polyamic acid solution, the imidizing agent and/or the dehydrating catalyst can be added directly without being dissolved in an organic solvent or can be dissolved in an organic solvent and then added.

Polymer (PI) obtained by imidization of polymer (PAA) according to any of the methods as above defined is characterized by improved dielectric properties, in particular in terms of low dielectric constant and low dielectric loss.

It has surprisingly been found that several properties of polymer (PI) can be fine tuned by controlling the relative amounts of diamines (D) and (D1) in the polymer.

The dielectric constant (Dk) of polymer (PI) is typically less than 4.0, even less than 3.5 and still less than 3.0 at 20 GHz.

The dielectric loss (DO of polymer (PI) is generally less than 0.0050 at 20 GHz. Surprisingly, it has been found that polymers (PI) with dielectric loss values of less than 0.0030 at 20 GHz, even of less than 0.0020 can be obtained by controlling the ratio of diamine (D) and diamine (D1) in the polymer.

Water uptake of the polymer (PI) of the present invention is<1% after immersion in water at room temperature for 24 h.

Polymer (PI), thanks to the peculiar monomer composition, is also characterized by being soluble in various organic solvents, in particular in organic polar solvents used in microelectronics industry such as N-methylpyrrolidone (NMP), γ-butyrolactone (GBL), propylene glycol monomethyl ether acetate (PGMEA) or cyclopentanone (CP).

As used herein “soluble” means that at least 99 wt % of polymer (PI) dissolves in said solvents to form a homogenous solution.

Notable non-limiting examples of polyimide polymers (PI) with remarkable electric properties are for instance polymers comprising units deriving from the polymerization of:
a) an aromatic tetracarboxylic anhydride selected from 4,4′-oxydiphthalic anhydride (ODPA) and 3,3′,4,4′-biphenyl tetracarboxylic dianhydride (BPDA),
b) 20.0 to 80.0 mol %, even 25 to 80 mol % of DAC6, and
c) 20.0 to 80.0 mol %, even 20 to 75 mol % p-phenylenediamine, (PDA).

A further object of the invention are compositions comprising the polyimide polymer (PI/PAA) and a polar organic solvent. The polyimide polymer (PI/PAA) is preferably dissolved in the solvent and the composition is thus a solution.

The solvent may be any of those capable of dissolving the polyimide polymer. For example, the solvent is selected from the group consisting of N,N-dimethylformamide, N,N-dimethylacetamide, N-methylpyrrolidone, N-vinylpyrrolidone, N-methylcaprolactam, dimethylsulfoxide, tetramethylurea, pyridine, dimethylsulfone, hexamethylsulfoxide, m-cresol, γ-butyrolactone, ethyl cellosolve, butyl cellosolve, ethyl carbitol, butyl carbitol, ethyl carbitol acetate, butyl carbitol acetate, ethylene glycol, ethyl lactate, butyl lactate, cyclohexanone, cyclopentanone, and mixtures thereof. Preferably, the solvent is selected from the group consisting of N-methylpyrrolidone and γ-butyrolactone.

The solvent is preferably present in an amount of 30 to 90 parts by weight, based on 100 parts by weight of the polyimide polymer.

Polyimide polymer (PI/PAA) of the present invention can be used in the manufacture of films or coatings. Films or coatings may be obtained with a process which comprises the steps of:
a) forming a film with the polymer (PI/PAA) composition; and
b) heat curing the film.

In step a) of the process, the polymer composition comprising the polyimide polymer (PI/PAA) and a polar organic solvent is applied to a substrate, typically by coating. The substrate may be glass or a silicon wafer. Any known coating process may be used, such as spin coating, slit spin coating, roll coating, die coating or curtain coating. Coating of the composition comprising the polyimide polymer (PI/PAA) leads to the formation of a film on the surface of the substrate, which is followed by thermosetting the applied composition by pre-baking the resulting film at a temperature comprised between 50 and 120° C., to allow the solvent to be volatilized.

The thickness of the film obtained in step a) may vary depending on the intended purpose. The thickness of the film is preferably in the range of from 0.1 to 100 microns, preferably from 1 to 50 micron, more preferably from 5 to 20 microns, even more preferably the thickness is of 10 to 15 microns.

In step b), the film is converted into a heat-resistant polyimide film by means of a further heat treatment step, typically referred to as “post-bake treatment”. Post-baking is usually performed at 150° C. to 300° C. for 1 to 120 minutes on a hot plate, or for 10 to 120 minutes at the same temperature range in an oven. A completely hardened polyimide film is obtained after post-baking.

The polyimide polymers (PI/PAA) of the present invention because of their excellent dielectric properties may find use in the electronic and semiconductor industries.

Conventional non-photosensitive polyimides can be used in photolithographic and etch processes (collectively referred to as masking processes) employed in semiconductor processing to fabricate patterns necessary to produce the various levels of a semiconductor process.

Photosensitive polyimides have significantly enhanced the development in microelectronics devices, since they offer the simplification of polyimide layer pattern generation by eliminating the need for a photoresist, resulting in productivity improvement and cost reduction.

Since the inventive polyimide polymer (PI/PAA) has excellent solubility in various polar organic solvents, it can be suitably used in patterning procedures involving positive- or negative-type pattern forming.

Accordingly a further object of the invention is a photosensitive composition comprising:
at least one polyimide polymer (PI/PAA), and
a photosensitive agent.

The photosensitive agent is preferably present in the photosensitive polymer composition in an amount of 1 to 50 parts by weight, based on 100 parts by weight of the polyimide polymer (PI/PAA).

The photosensitive polymer composition of the present invention may further comprise one or more additives selected from dissolution rate modifiers, sensitizers, adhesion promoters and surfactants. 0.1 to 20 parts by weight of each of the additives can be used for every 100 parts by weight of the polyimide polymer (PI/PAA). Suitable sensitizers may be selected from perylene, anthracene, thioxanthone, Michler's ketone, benzophenone and fluorene. Suitable adhesion promoters may be selected from 3-(trimethoxysilyl)propyl methacrylate, N-[3-(trimethoxy-si)propyl]aniline, trimethoxy(3,3,3-trifluoropropyl)silane.

In a preferred embodiment, the photosensitive polymer composition of the present invention comprises:
from 1 to 70 parts by weight of polyimide polymer (PI/PAA);
from 1 to 30 parts by weight of a photosensitive agent,
from 0 to 20 parts by weight of one or more additives as above defined,
with respect to a total of 100 parts by weight of the photosensitive polymer composition.

According to the present invention, any photosensitive agent can be used which decreases or increases the solubility of polyimide polymer (PI/PAA) after exposure to actinic radiation. In such a way the solubility of the polymer which has been exposed to actinic radiation is differentiated from that of the non-exposed polymer and an appropriate pattern can be obtained.

The photosensitive polymer composition of the present invention can be used in a pattern forming method, said method comprising:
a) applying a coating of the photosensitive polymer composition on a substrate;
b) masking the applied coating with a photomask having a pattern;
c) exposing the masked substrate to a source of actinic radiation and developing the substrate; and
d) heat curing the developed substrate to form a polyimide pattern.

Step a) of the process corresponds essentially to step a) of the process for making a film of polyimide polymer (PI/PAA) as detailed above.

In step b) of the process, the coating of photosensitive polymer composition provided in step a) is masked by a photomask having a predetermined pattern and it is exposed, along with the photomask to actinic radiation. Exposure is performed with radiation at a suitable wavelength and for a sufficient time to promote the desired change in the polyimide polymer (PI/PAA) solubility which is required.

Actinic radiation used for the exposure process is not particularly limited. For example, electromagnetic radiation, visible light, UV light, electron beam, X ray or a laser can be used to irradiate the photosensitive film.

Thereafter, the exposed photosensitive film is developed with a developer to remove the exposed or non-exposed region, leaving the desired pattern.

The developer is not particularly limited and it depends on whether a positive-type or a negative-type pattern formation is performed.

After development, the developed substrate is converted into heat-resistant polyimide film through a post-bake treatment, usually at 150° C. to 300° C. for 1 to 120 minutes. A completely hardened polyimide pattern is obtained after postbaking.

In the case of positive-type pattern forming, solubility of the exposed film is generally improved so that upon treatment with appropriate developer solutions the region of the substrate exposed to actinic radiation is removed.

In a first embodiment of the invention photosensitive compositions suitable for use in positive-type pattern forming methods are provided.

Suitable compounds used as the photosensitive agent for said positive-type pattern forming method include, for example, o-quinone diazide compounds, azide compounds and diazo compounds. O-quinone diazide compounds are preferred in terms of sensitivity or resolution.

The o-quinone diazide compound can be selected from a great number of compounds of various structures having at least one o-quinone diazide group, in which the solubility is modified upon irradiation.

In particular, various o-quinone diazide sulfonic acid esters or sulfone amides are preferred.

The following o-quinone diazide sulfonic acid esters can suitably be used as photo sensitive agent in the present invention:

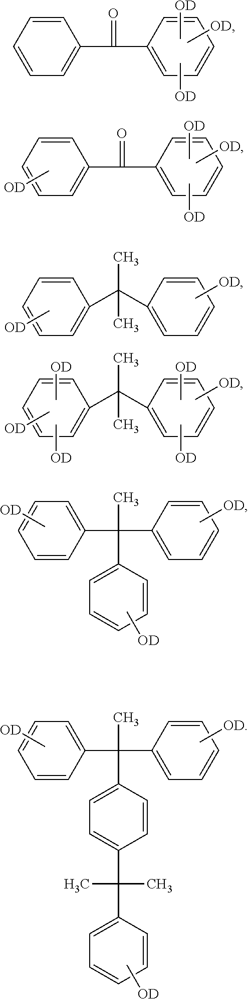

wherein in each of the formulas above, D is selected from the following compounds:

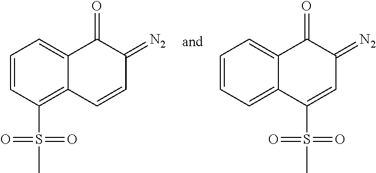

Typical examples of o-quinone diazide sulfonic acid esters are 2,2′-dihydroxy-diphenyl-bis-(naphthoquinone-1,2-diazide-5-sulfonic acid ester), 2,3,4-trihydroxybenzophenone bis-(naphthoquinone-1,2-diazide-5-sulfonic acid ester), 2,7-dihydroxynaphthalene-bis-(naphthoquinone-1,2-diazide-5-sulfonic acid ester) and the ester of a phenol formaldehyde resin and naphthoquinone-1,2-diazide-5-sulfonic acid.

Suitable developers for positive-type pattern forming compositions and emthods are water, an organic solvent, an alkaline aqueous solution or a mixture thereof. Suitable alkaline aqueous solutions include aqueous solutions of an alkali metal or alkaline earth metal hydroxide or carbonate, a hydrogen carbonate, ammonia water or a quaternary ammonium salt.

The developer may contain a surfactant, a defoaming agent, an organic base (e.g., benzylamine, ethylenediamine, ethanolamine, tetramethylammonium hydroxide, diethylenetriamine, triethylenepentamine, morpholine or triethanolamine), an organic solvent as a development promoter (e.g., an alcohol, a ketone, an ester, an ether, an amide or a lactone), etc.

In an alternative embodiment of the invention, photosensitive compositions which are particularly suitable for use in a negative-type pattern forming method are provided. In such an embodiment polyimide polymer (PI/PAA) is preferably obtained by polymerizing: a component (AC) selected from those of formula (V) wherein R₂ is selected from C₄-C₂₀ alkyl radicals comprising at least one polymerizable group, a diamine (D), and optionally a diamine (D1).

Particularly advantageous are compositions comprising a polyimide polymer (PI/PAA) obtained by polymerizing:
a component (AC) selected from those of formula (V) wherein R₂ is selected from C₄-C₂₀ alkyl radicals comprising at least on polymerizable group of formula (P-1); preferably R₂ is —(CH₂)ₚ—O—C(O)C(R*)═CH₂, where R* is H or a C₁-C₅ alkyl group, and p is an integer from 1 to 5;more preferably R₂ is —(CH₂)ₚ—O—C(O)C(CH₃)═CH₂, with p equal to 1 or 2;
5.0 to 100.0 mol %, 10.0 to 85.0 mol %, even 15.0 to 80.0 mol % of a diamine (D) of formula (II), (III) or (IV), preferably DAC6, and
0.0 to 95.0 mol %, 15.0 to 90.0 mol %, even 20.0 to 85.0 mol % of a diamine (D1) selected from 4,4′-diaminodiphenyl ether (ODA) and p-phenylenediamine, (PDA).

The photosensitive agent in said compositions is selected among those compounds which are capable, under actinic radiation, to promote the polymerization of the polymerizable groups which are present in component (AC) of formula (V). Suitable photosensitive agents may be selected among known radical

polymerization initiators. Non-limiting examples are for instance: acylphosphine oxides, such as bis(2,4,6-trimethylbenzoyl)-phenylphosphineoxide, benzophenone and its derivatives, such as 4,4′-bis(dimethylamino)benzophenone, oximes and oxime esters, such as 1-phenylpropanedione-2-(o-methoxycarbonyl)oxime, 1-phenyl-3-ethoxy-propanetrione-2-(o-benzoyl)oxime; acetophenone derivatives, such as 2-hydroxy-2-methylpropiophenone, 2,2′-diethoxyacetophenone.

The photosensitive composition may further comprise cross-linking agents. Non-limiting examples of suitable cross-linking agents are triallylisocyanurate (TAIC), bisphenol A dimethacrylate and its derivatives, 1,6-hexanediol diacrylate, trimethylolpropane triacrylate (TMPTA), trimethylolpropane methacrylate (TMPTMA), dipentaerythritol hexaacrylate, dipentaerythritol methacrylate.

When the photosensitive polymer composition of the present invention is used in a negative-type pattern forming method in step c) of the method the exposed substrate is developed with a developer to remove the polyimide polymer (PI/PAA) in the non-exposed region of the substrate, leaving the desired pattern.

The developer is not particularly limited. As the developer, there can be exemplified any solvent in which the polyimide polymer (PI/PAA) is soluble, such as cyclopentanone, gamma-butyrolactone, 1-methoxy-2-propanol acetate, Rhodiasolv® Polar clean, N-methyl-2-pyrrolidone (NMP).

In the case of using a polyimide polymer (PI) as polymer (PI/PAA) in the photosensitive polymer composition, conversion of polyamic acid precursor into a polyimide is not involved, and thus the relief pattern can be formed at a lower temperature. The pattern-forming method in this case thus requires in step d) a low postbaking temperature, typically the range of from 180 to 200° C.

In the alternative case of using a polyamic acid polymer (PAA) as polymer (PI/PAA) in the photosensitive polymer composition, the developed film containing a polyamic acid precursor is subjected in step d) to a thermal process to have the full imidization and postbaking of the film. The developed film containing a polyimide precursor is thus heated at a temperature of at least 300° C., preferably in the range of from 300 to 350° C., to convert the polyamic acid into a polyimide and curing the resulting film to obtain the final polyimide pattern.

The polyimide polymer (PI/PAA) of the present invention as well as the photosensitive compositions comprising the polyimide polymer (PI/PAA) are suitable for the formation of interlayer insulating films, passivation films, buffer coating films or as insulating films for multilayer printed boards of semiconductor devices. The polymer composition of the present invention is suitable for the formation of redistribution layers in microchips.

Accordingly a further object of the invention are articles comprising the polyimide polymer (PI/PAA) of the invention. In particular, articles comprising at least one layer comprising the polyimide polymer (PI/PAA) of the invention.

All the preferences detailed above in respect of polyamic acid polymer (PAA), polyimide polymer (PI) and polyimide polymer (PI/PAA) equally apply to the compositions comprising at least one of said polymers as well as to the films or articles obtained therefrom as well as to the methods for making a film or a pattern.

Should the disclosure of any patents, patent applications, and publications which are incorporated herein by reference conflict with the description of the present application to the extent that it may render a term unclear, the present description shall take precedence.

The invention will be now described with reference to the following examples, whose purpose is merely illustrative and not !imitative of the present invention.

### EXAMPLES

### Raw materials

4,4′-(perfluorohexane-1,6-diyl)dianiline (DAC6) was prepared according to the

method described in P. V. Herrera, H. Ishida, Journal of Fluorine Chemistry 130 (2009) 573-580.

4,4′-(perfluorohexane-1,4-diyl)dianiline (DAC4) was prepared according to the method described in P. V. Herrera, K. Doyama, H. Abe, H. Ishida, Macromolecules 2008, 41, 9704-9714.

HEMA2-BPDA, the methyl ester/acid chloride derivative of BPDA (Me-BDPA) and the methyl ester/acid chloride derivative of ODPA (Me-ODPA) were prepared according to the method disclosed in U.S. Pat. No. 4,040,831.

3,3′,4,4′-biphenyl tetracarboxylic dianhydride (BPDA), commercially available from Sigma Adrich.

4,4′-(hexafluoroisopropylidene)diphthalic anhydride (6-FDA), commercially available from Chem-Impex Int'l Inc.

4,4′-oxydiphthalic anhydride (ODPA), commercially available from TCI Chemicals (India) Pvt. Ltd.

p-phenylenediamine (PDA), commercially available from TCI Chemicals (India) Pvt. Ltd.

2,2-Bis(4-aminophenyl)hexafluoropropane (BPAFDA), commercially available from TCI Chemicals (India) Pvt. Ltd.

Bis(4-aminophenoxy)hexafluorocyclobutane (DPFCB-N) was prepared according to the method described in WO2020/229227.

Photo sensitive agent: 2,3,4-trihyoxybenzophenone bis-(naphthoquinone-1,2-diazide-5-sulfonic acid ester in GBL (total solid concentration: 30 wt %; GBL: 65 wt %), commercially available from Miwon Commercial Co., Ltd.

Tetramethylammoniumhydroxide (TMAH), commercially available from Sigma Aldrich.

For polyimide synthesis, dianhydrides 6-FDA, ODPA, and BPDA were purified by vacuum sublimation before the reaction. The amines PDA, DAC4 and DAC6 were freshly distilled/crystallized before use and stored under inert atmosphere in the dark. All the solvents were freshly distilled and dried as per standard drying procedure before the reaction.

### Mechanical Property Measurements

Mechanical properties were measured on a ZWICK Z030 with 1N load cell using ASTM D638 Type V specimen, speed 10 mm/min.

Dynamic mechanical analyzer (DMA) was performed on polyimide films using TA instrument RSA-G2 from 25° C. to 350° C. with temperature ramping rate 3° C./min under nitrogen.

### Thermal Analysis:

TGA measurements were performed on a Q500-TA instruments in N2 atmosphere.

DSC measurements were performed on a Q2000-TA instruments in N2 atmosphere.

Dielectric measurement: Dielectric constant (Dk) and dielectric loss (Df) were measured at 20 GHz using split cylinder dielectric resonator following IPC-TM-650 2.5.5.13 standard method.

### Viscosity Measurement:

Viscosity of polyamic acid solution was measured by Brookfield Viscometer at 30° C. (200 rpm, spindle 34).

Viscosity of polyimide resin was measured by Dilute Solution Viscometer in NMP at 30° C. at 0.75 wt % of solid concentration (SI Analytics, capillary number: 1068421).

### Example 1. Preparation of Polyamic Acid A1

In a typical polymerization, a three-necked round bottom flask, equipped with magnetic stirrer, nitrogen inlet/outlet was charged with 4,4′-(perfluorohexane-1,6-diyl)dianiline (DAC6) (38.7 mmol) and dimethylacetamide (DMAc, hereinafter) (15 wt % solid content). To this stirring solution, 4,4′-oxydiphthalic anhydride (ODPA) (38.7 mmol) was added in portion and the resulting solution was allowed to stir at room temperature for 8 h to obtain a viscous poly(amic acid) solution which was stored in refrigerator for further use. Composition and solubility in some solvents of Al are shown in Table 1.

### Examples 2-15 and Comparative Examples CA1-CA4

Following the procedure of Example 1, further polyamic acids according to the invention, identified as A2 to A15 and comparative examples CA1 to CA4 were prepared starting from different diamine compounds as well as mixtures of diamine compounds and different dianhydride compounds. Compositions and solubility in some solvents of the resulting polyamic acids are shown in Table 1, wherein the molar ratios of the different components in the polyamic acid polymer are provided, and Table 2.

TABLE 1

| | ANHYDRIDE | | | AMINE (D) | | AMINE (D1) | | | |
|---|---|---|---|---|---|---|---|---|---|
| | 6-FDA | ODPA | BPDA | DAC4 | DAC6 | PDA | ODA | DPFCB-N | BPAFDA |
| A1 | 1.00 | | | | 1.00 | | | | |
| A2 | 1.00 | | | 1.00 | | | | | |
| A3 | 1.00 | | | | 0.50 | | | 0.50 | |
| A4 | | 1.00 | | | 1.00 | | | | |
| A5 | | 1.00 | | | 0.75 | 0.25 | | | |
| A6 | | 1.00 | | | 0.50 | 0.50 | | | |
| A7 | | 1.00 | | | 0.25 | 0.75 | | | |
| A8 | | 1.00 | | | 0.20 | 0.80 | | | |
| A9 | | 1.00 | | | 0.50 | | 0.50 | | |
| A10 | | 1.00 | | | 0.25 | | 0.75 | | |
| A11 | | | 1.00 | | 1.00 | | | | |
| A12 | | | 1.00 | | 0.75 | 0.25 | | | |
| A13 | | | 1.00 | | 0.50 | 0.50 | | | |
| A14 | | | 1.00 | | 0.25 | 0.75 | | | |
| A15 | | | 1.00 | | 0.18 | 0.82 | | | |
| CA1 | 1.00 | | | | | | | | 1.00 |
| CA2 | | 1.00 | | | | | | | 1.00 |
| CA3 | | 1.00 | | | | 1.00 | | | |
| CA4 | | | 1.00 | | | 1.00 | | | |

TABLE 2

| | Solubility* | | |
|---|---|---|---|
| | DMAc | NMP | GBL |
| A1 | S | S | S |
| A2 | S | S | S |
| A3 | S | S | S |
| A4 | S | S | S |

*S means soluble, giving a homogeneous solution

### Example 16: Polyimide Polymer Preparation

Under the flow of dry nitrogen, diamine compound DAC6 (4 g, 8.3 mmol) was dissolved in NMP (30 mL). To this stirring solution, dianhydride compound 6-FDA (3.74 g, 8.43 mmol) was added in portion and the solution was stirred at 25° C. for 8 h. Subsequently, toluene (12 mL), GBL (0.145 g, 1.65 mmol) and pyridine (0.26 g, 3.3 mmol) were added and the temperature was raised to 180° C. The solution was stirred at this temperature for 4 h while the water was removed by azeotropic distillation. The solution was cooled down to room temperature and the polyimide resin was precipitated from water and filtered. The polymer powder was washed with hot water, followed by washing with MeOH and dried in vacuum oven at 90° C. for 8 h. Polyimide B1 was thus obtained.

Following the same procedure, but using DAC4 instead of DAC6, polyimide B2 was obtained.

Viscosity and solubility in some solvents is shown in Table 3.

TABLE 3

| | |
|---|---|
| Inherent | Solubility * |
| Viscosity | (25% solid concentration, 25° C.) |

| | (mL/g) | NMP | DMAc | GBL | PGMA | CP |
|---|---|---|---|---|---|---|
| B1 | 0.16 | S | S | S | S | S |
| B2 | 0.19 | S | S | S | S | S |

* S means soluble, giving a homogeneous solution.

The data demonstrate that the polyimide polymers B1 and B2 of the present invention are soluble in many different solvents.

For the person skilled in art, inherent viscosity of a polymer can be adjusted based on monomer stoichiometry.

### Example 17: Polyimide Film Preparation for Dielectric Measurement

The viscous polyamic acid solutions as obtained in Examples 1-15 and Comparative Examples CA1, CA2 and CA4 were filtered through PTFE syringe (0.45 μ) and cast on a glass substrate by bar-coating. Each cast film was transferred to a flat oven and slowly cured at a temperature from 50° C. to 300° C. and finally at 300° C. for 1.0 h to obtain transparent films (Thickness: 30-40 micron).

Dielectric properties, thermal analyses and mechanical properties of obtained films F1-F15 and comparative films CF1-CF4 are shown in Table 4 and Table 5.

TABLE 4

| | | | | | | | | | | Dielectric | |
|---|---|---|---|---|---|---|---|---|---|---|---|
| | ANHYDRIDE | | | AMINE (D) | | AMINE (D1) | | | | properties | |
| | 6-FDA | ODPA | BPDA | DAC4 | DAC6 | PDA | ODA | BPAFDA | DPFCB-N | Dk | Df |
| F1 | 1.00 | | | | 1.00 | | | | | 2.4 | 0.0027 |
| F2 | 1.00 | | | 1.00 | | | | | | 2.4 | 0.0037 |
| F3 | 1.00 | | | | 0.50 | | | | 0.50 | 2.6 | 0.0038 |
| F4 | | 1.00 | | | 1.00 | | | | | 3.0 | 0.0027 |
| F5 | | 1.00 | | | 0.75 | 0.25 | | | | 3.4 | 0.0015 |
| F6 | | 1.00 | | | 0.50 | 0.50 | | | | 3.2 | 0.0023 |
| F7 | | 1.00 | | | 0.25 | 0.75 | | | | 3.1 | 0.0013 |
| F8 | | 1.00 | | | 0.20 | 0.80 | | | | 3.3 | 0.0024 |
| F9 | | 1.00 | | | 0.50 | | 0.50 | | | 2.9 | 0.0027 |
| F10 | | 1.00 | | | 0.25 | | 0.75 | | | 2.9 | 0.0044 |
| F11 | | | 1.00 | | 1.00 | | | | | 2.9 | 0.0017 |
| F12 | | | 1.00 | | 0.75 | 0.25 | | | | 3.3 | 0.0014 |
| F13 | | | 1.00 | | 0.50 | 0.50 | | | | 2.9 | 0.0016 |
| F14 | | | 1.00 | | 0.25 | 0.75 | | | | 3.2 | 0.0024 |
| F15 | | | 1.00 | | 0.18 | 0.82 | | | | 3.7 | 0.0035 |
| CF1 | 1.00 | | | | | | | 1.00 | | 2.8 | 0.0075 |
| CF2 | | 1.00 | | | | | | 1.00 | | 2.7 | 0.0062 |
| CF3 | | 1.00 | | | | 1.00 | | | | 3.5 | 0.0037 |
| CF4 | | | 1.00 | | | 1.00 | | | | 3.5 | 0.0068 |

The data in Table 4 show that the polyimides of the present invention are characterized by improved dielectric properties in comparison with polyimides prepared by polymerizing different diamine monomers. In particular, the Applicant has surprisingly found that the selection of some specific organic fluorinated diamines as monomers for preparing the polyimides of the present invention allows obtaining polyimides dielectric loss values Df not previously achieved.

TABLE 5

| | Thermal Properties | | | | |
|---|---|---|---|---|---|
| | | Isothermal TGA | Mechanical properties | | |
| | TGA | (300° C./1 h), % | Tanδ | Strength | Modulus |
| | (5% loss/° C.) | loss | (DMA) | (MPa) | (GPa) |
| F1 | 530 | 0.2 | 236 | 80 | 2.3 |
| F2 | 515 | 0.1 | 247 | 99 | 2.8 |
| F3 | 506 | 0.3 | 249 | 91 | 2.8 |
| F4 | 531 | 0.6 | 231 | 100 | 4.0 |
| F5 | 530 | 0.0 | — | 105 | 3.7 |
| F6 | 540 | <0.1 | >300 | 134 | 4.0 |
| F7 | 530 | 0.0 | 370 | 114 | 4.0 |
| F8 | 535 | 0.0 | 329 | 150 | 5.0 |
| F9 | 530 | 0.0 | 233 | 106 | 3.0 |
| F10 | 513 | 0.0 | 250 | 109 | 3.0 |
| F11 | 561 | <0.1 | 352 | 106 | 4.0 |
| F12 | 562 | <0.2 | 325 | 126 | 7.0 |
| F13 | 565 | <0.1 | 311 | 134 | 5.0 |
| F14 | 551 | 0.0 | 322 | 200 | 7.0 |
| F15 | 560 | 0.2 | 300 | 193 | 5.0 |
| CF1 | 509 | 0.2 | 317 | 70 | 3.4 |
| CF2 | 526 | 0.6 | 297 | 110 | 3.0 |
| CF3 | 555 | 0.2 | 340 | 152 | 6.0 |
| CF4 | 570 | 0.5 | 337 | 248 | 9.0 |

The data in Table 5 show that the inventive polyimide polymers possess the good mechanical properties usually associated with other polyimides as well as excellent thermal resistance (as indicated by TGA analysis).

### Example 18: Preparation of Polyamic Esters A16-A20

In a typical diester preparation, a three-necked round bottom flask, equipped with magnetic stirrer, reflux condenser, nitrogen inlet/outlet was charged with 3,3′,4,4′-biphenyl tetracarboxylic dianhydride (BPDA) (0.102 mol) and dry methanol (20 wt % solid content); subsequently the solution was refluxed for 6 h to obtain a clear solution. Next, the solution was cooled down to room temperature and evaporated under vacuum to obtain a sticky mass, to which toluene (50 mL) was added and evaporated under vacuum to obtain white solid powder of di-methyl ester of 3,3′,4,4′-biphenyltetracarboxylic acid.

Next, the flask was cooled at 0° C., to which thionyl chloride (0.5 mol) was added dropwise with a catalytic amount of dimethylformamide. Subsequently, the solution was stirred at 50° C. for 2 h to obtain a clear solution. Next, the excess thionyl chloride was removed with toluene under reduced pressure to obtain di-methyl 3,3′,4,4′-biphenyltetracarboxylate dichloride.

In a typical polyamic ester preparation, a three-necked round bottom flask, equipped with magnetic stirrer, nitrogen inlet/outlet was charged with di-methyl 3,3′,4,4′-biphenyltetracarboxylate dichloride (0.02 mol), pyridine (0.04 mol) in dimethyl acetamide was added dropwise a mixture of 4,4′-(perfluorohexane-1,6-diyl)dianiline (DAC6) (0.005 mol) and p-phenylenediamine (0.015 mol) at 0° C. (15 wt % solid concentration). Subsequently, the reaction mixture was stirred at room temperature for 16 h to obtain a viscous polyamic ester solution which was stored in the refrigerator for further use.

Following the same procedure polyamic esters according to the invention, identified as A16 to A20 were prepared starting from different diamine compounds as well as mixtures of diamine compounds. Compositions and inherent viscosity of the resulting polyamic acids are shown in Table 6, wherein the molar ratios of the different components in the polyamic ester polymer are provided.

TABLE 6

| | ANHYDRIDE COMPONENT | | | AMINE | AMINE | Inherent |
|---|---|---|---|---|---|---|
| | HEMA2- | Me- | Me- | (D) | (D1) | viscosity |
| | BPDA | BPDA | ODPA | DAC6 | PDA | (dL/g) |
| A16 | 1.00 | | | 1.00 | | 0.13 |
| A17 | 1.00 | | | 0.50 | 0.50 | 0.12 |
| A18 | 1.00 | | | 0.20 | 0.80 | 0.14 |
| A19 | | 1.00 | | 0.25 | 0.75 | 0.21 |
| A20 | | | 1.00 | 0.25 | 0.75 | 0.22 |

### Example 19: Photo-Patterning of Polyamic Acid

A 10-μm thick photosensitive film was prepared by dissolving polyamic acid powder obtained as in Example 1 and a sensitive agent to obtain a composition comprising: polyamic acid 70 wt %, photosensitive agent 30 wt %, GBL: 65 wt %. This photosensitive composition was spin coated on a silicon wafer and the resulting film was pre-baked at 60° C./5 min, and 90° C./5 min. Afterwards, the thin film along with a mask, was exposed to UV light (400-600 mJ/cm²), and developed with 2.38 wt % of aqueous TMAH solution, followed by rinsing with water or water/isopropanol mixture to obtain positive tone photo-patterning. Subsequently, the wafer was post baked in an oven under the flow of nitrogen where the temperature was raised slowly to ˜300° C. and finally the sample was cured at 300° C. for 1 h to obtain the final pattern.

### Example 20: Photo-Patterning of Polyimide Polymer

A 10-μm thick photosensitive film was prepared by dissolving polyimide resin and photosensitive agent to obtain a composition comprising: polyimide 70 wt %, photosensitive agent 30 wt %, GBL: 65 wt %. This photosensitive composition was spin coated on a silicon wafer and the resulting film was This photosensitive composition was spin coated on a silicon wafer and the resulting film was pre-baked at 60° C./10 min, and 90° C./10 min. Afterwards, the thin film along with a mask, was exposed to UV light (400-600 mJ/cm²), and developed in a solvent mixture of ethanolamine/GBL/water at 25° C. for 2-5 minutes, followed by rinsing with water to obtain positive tone photo-patterning. Subsequently, the sample was cured in an oven at 190° C./30 min under the flow of nitrogen to obtain the final pattern.

### Example 21: Photo-Patterning of Polyamic Ester (Positive Tone)

A 10-μm thick photosensitive film was prepared by dissolving polyamic ester powder obtained as in Example A19 and a photosensitive agent to obtain a composition comprising: NMP: 65 wt % and solid content: 35 wt % in which polyamic ester 70 wt %, photosensitive agent 30 wt %. This photosensitive composition was spin coated on a silicon wafer and the resulting film was pre-baked at 60° C./5 min, and 90° C./5 min. Afterwards, the thin film along with a mask, was exposed to UV light (400-600 mJ/cm²), and developed with 2.38 wt % of aqueous TMAH solution, followed by rinsing with water or water/isopropanol mixture to obtain positive tone photo-patterning.

Subsequently, the wafer was post baked in an oven under the flow of nitrogen where the temperature was raised slowly to ˜300° C. and finally the sample was cured at 300° C. for 1 h to obtain the final pattern.

### Example 21: Photo-Patterning of Polyamic Ester (Negative Tone)

A photosensitive film was prepared by dissolving polyamic ester powder obtained as in Example A18 and essential additive to obtain a composition comprising: DMAc 65 wt % and solid content 35 wt % in which polyamic ester (85 parts), crosslinking agent (10 parts), photoinitiator (3 parts) and adhesion promoter (2 parts). This photosensitive composition was spin coated on silicon wafer and resulting film was pre-baked at 80° C./5 min. Afterwards thin film along with a mask was exposed to UV light (400-600 mJ/cm²) and developed with NMP solvent, followed by rinsing with water to obtain negative tone photo-patterning. Subsequently, the wafer was post-baked in an oven under the flow of nitrogen where the temperature was raised slowly to ˜300° C. and finally the sample was cured at 300° C. for 1 h to obtain the final pattern.

1. A polyamic acid polymer, [polymer (PAA)], obtained by polymerizing:
an aromatic carboxylic acid component [component (AC)];
a diamine component [diamine (D)], wherein diamine (D) is an organic fluorinated diamine of formula (I): 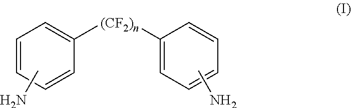
with n being an integer from 2 to 10; and
optionally, a diamine component [diamine (D1)] different from diamine (D).

2. The polymer (PAA) according to claim 1 wherein component (AC) is an aromatic tetracarboxylic anhydride, selected from the group consisting of pyromellitic dianhydride (PMDA), 3,3′,4,4′-biphenyl tetracarboxylic dianhydride (BPDA), 4,4′-oxydiphthalic anhydride (ODPA), isomeric diphenyl sulfide dianhydride (TDPA), triphenyl diether dianhydride (HQDPA), 3,3′,4,4′-benzophenone tetracarboxylic dianhydride (BTDA), 4,4′-bisphenol A dianhydride (BPADA), 3,3′,4,4′-diphenyl sulfone tetracarboxylic dianhydride (DSDA), 4,4′-(hexafluoroisopropylidene)diphthalic anhydride (6-FDA), 9,9-bis (trifluoromethyl)xanthene tetracarboxylic dianhydride (6FCDA), 1,4-bis(trifluoromethyl)-2,3,5,6 pyromellitic dianhydride (P6FDA), 1,4-bis(3,4-dicarboxy-trifluorophenoxy)tetrafluorobenzene dianhydride (10-FEDA), 2,2-bis[4-(3,4-dicarboxyphenoxy) phenyl] hexafluoropropane dianhydride (BFDA) or 1,4-difluoro pyromellitic dianhydride (PF2DA).

3. The polymer (PAA) according to claim 2 wherein component (AC) is selected from the group consisting of pyromellitic dianhydride (PMDA), 4,4′-oxydiphthalic anhydride (ODPA) and 4,4′-(hexafluoroisopropylidene)diphthalic anhydride (6-FDA), 3,3′,4,4′-biphenyl tetracarboxylic dianhydride (BPDA).

4. The polymer (PAA) according to claim 1 wherein component (AC) is selected from compounds of formula (V): 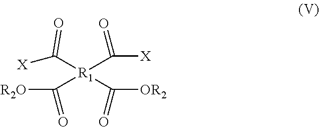
wherein R₁ is an aromatic tetravalent group, which may comprise one or more than one aromatic ring, which may be optionally fused together, R₂ is a C₁-C₂₀ alkyl radical, optionally comprising at least one polymerizable group, and X is OH, Cl, Br, I, preferably OH or Cl.

5. The polymer (PAA) of claim 1 comprising:
5.0 to 95.0 mol % of the total amount of moles of diamine units in the polymer of diamine (D), and
5.0 to 95.0 mol % of the total amount of moles of diamine units in the polymer of diamine (D1).

6. The polymer (PAA) of claim 1 obtained by polymerizing:
a component (AC) selected from 4,4′-oxydiphthalic anhydride (ODPA), 3,3′,4,4′-biphenyl tetracarboxylic dianhydride (BPDA), and a compound of formula (V);
5.0 to 95.0 mol %, 15.0 to 85.0 mol %, even 20.0 to 80.0 mol % of the total amount of moles of diamine units in the polymer of a diamine (D) of formula (II), and 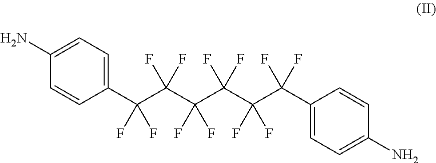 [SMILES: Nc1ccc(C(F)(F)C(F)(F)C(F)(F)C(F)(F)C(F)(F)C(F)(F)c2ccc(N)cc2)cc1]
5.0 to 95.0 mol %, 15.0 to 85.0 mol %, even 20.0 to 80.0 mol % of the total amount of moles of diamine units in the polymer of diamine (D1) selected from 4,4′-diaminodiphenyl ether (ODA), p-phenylenediamine, (PDA).

7. A polyimide polymer, [polymer (PI)], obtained from polymer (PAA) of claim 1.

8. A polyimide polymer (PI) comprising units derived from the polymerization of:
a component (AC) selected from 4,4′-oxydiphthalic anhydride (ODPA), 3,3′,4,4′-biphenyl tetracarboxylic dianhydride (BPDA),
20.0 to 80.0 mol % of a diamine (D) of formula (II), and
20.0 to 80.0 mol % of p-phenylenediamine, (PDA).

9. A composition comprising a polymer selected from the group consisting of a polymer (PAA) of claim 1 or a polymer (PI) obtainable from polymer (PAA) and a polar organic solvent.

10. A photosensitive polymer composition comprising a polymer selected from the group consisting of a polymer (PAA) of claim 1 or a polymer (PI) obtainable from polymer (PAA) and a photosensitive agent.

11. A pattern forming method, said method comprising:
a) applying a coating of the photosensitive polymer composition of claim 10 on a substrate;
b) masking the applied coating with a photomask having a pattern;
c) exposing the masked substrate obtained in step b) to a source of actinic radiation and developing the substrate; and
d) heat curing the developed substrate obtained in step c) to form a polyimide pattern.

12. The method of claim 10 wherein the photosensitive agent is selected from the group of o-quinone diazide compounds, azide compounds and diazo compounds.

13. The method of claim 11 wherein the photosensitive composition comprises a polymer selected from the group consisting of a polymer (PAA) of claim 1 and a polymer (PI) obtained from polymer (PAA), obtained by polymerizing a component (AC) of formula (V) wherein R₂ is a C₁-C₂₀ alkyl radical comprising at least one polymerizable group and wherein the photosensitive agent is selected from the group consisting of acylphosphine oxides, such as bis(2,4,6-trimethylbenzoyl)-phenylphosphineoxide, benzophenone and its derivatives, such as 4,4′-bis(dimethylamino)benzophenone, oximes and oxime esters, such as 1-phenylpropanedione-2-(o-methoxycarbonyl)oxime, 1-phenyl-3-ethoxy-propanetrione-2-(o-benzoyl)oxime; acetophenone derivatives, such as 2-hydroxy-2-methylpropiophenone, 2,2′-diethoxyacetophenone.

14. An article comprising at least one polymer selected from the group consisting of the polymer (PAA) of claim 1 and the polymer (PI) obtained from polymer (PAA).

15. A printed board of a semiconductor device or a microchip comprising at least one layer comprising a polymer (PAA) of claim 1 and/or a polymer (PI) obtained from polymer (PAA).

1. A polyamic acid polymer, [polymer (PAA)], obtained by polymerizing:
an aromatic carboxylic acid component [component (AC)];
a diamine component [diamine (D)], wherein diamine (D) is an organic fluorinated diamine of formula (I): 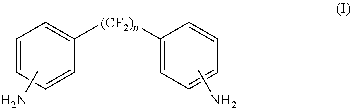
with n being an integer from 2 to 10; and
optionally, a diamine component [diamine (D1)] different from diamine (D).

2. Polymer (PAA) according to claim 1 wherein component (AC) is an aromatic tetracarboxylic anhydride, preferably selected from the group consisting of pyromellitic dianhydride (PMDA), 3,3′,4,4′-biphenyl tetracarboxylic dianhydride (BPDA), 4,4′-oxydiphthalic anhydride (ODPA), isomeric diphenyl sulfide dianhydride (TDPA), triphenyl diether dianhydride (HQDPA), 3,3′, 4,4′-benzophenone tetracarboxylic dianhydride (BTDA), 4,4′-bisphenol A dianhydride (BPADA), 3,3′,4,4′-diphenyl sulfone tetracarboxylic dianhydride (DSDA), 4,4′-(hexafluoroisopropylidene)diphthalic anhydride (6-FDA), 9,9-bis (trifluoromethyl)xanthene tetracarboxylic dianhydride (6FCDA), 1,4-bis(trifluoromethyl)-2,3,5,6 pyromellitic dianhydride (P6FDA), 1,4-bis(3,4-dicarboxy-trifluorophenoxy)tetrafluorobenzene dianhydride (10-FEDA), 2,2-bis[4-(3,4-dicarboxy phenoxy) phenyl] hexafluoropropane dianhydride (BFDA) or 1,4-difluoro pyromellitic dianhydride (PF2DA).

3. Polymer (PAA) according to anyone of claim 1 or 2 wherein component (AC) is selected from the group consisting of pyromellitic dianhydride (PMDA), 4,4′-oxydiphthalic anhydride (ODPA) and 4,4′-(hexafluoroisopropylidene)diphthalic anhydride (6-FDA), 3,3′,4,4′-biphenyl tetracarboxylic dianhydride (BPDA).

4. Polymer (PAA) according to claim 1 wherein component (AC) is selected from compounds of formula (V): 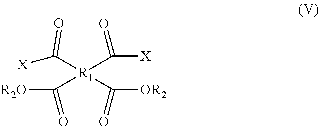
wherein R₁ is an aromatic tetravalent group, which may comprise one or more than one aromatic ring, which may be optionally fused together, R₂ is a C₁-C₂₀ alkyl radical, optionally comprising at least one polymerizable group, and X is OH, CI, Br, I, preferably OH or Cl.

5. Polymer (PAA) of anyone of claims 1 to 4 comprising:
5.0 to 95.0 mol %, 15.0 to 85.0 mol %, even 20.0 to 80.0 mol % of the total amount of moles of diamine units in the polymer of diamine (D), and
5.0 to 95.0 mol %, 15.0 to 85.0 mol %, even 20.0 to 80.0 mol % of the total amount of moles of diamine units in the polymer of diamine (D1).

6. Polymer (PAA) of anyone of claims 1 to 5 obtained by polymerizing:
a component (AC) selected from 4,4′-oxydiphthalic anhydride (ODPA), 3,3′,4,4′-biphenyl tetracarboxylic dianhydride (BPDA), and a compound of formula (V);
5.0 to 95.0 mol %, 15.0 to 85.0 mol %, even 20.0 to 80.0 mol % of the total amount of moles of diamine units in the polymer of a diamine (D) of formula (II), and
5.0 to 95.0 mol %, 15.0 to 85.0 mol %, even 20.0 to 80.0 mol % of the total amount of moles of diamine units in the polymer of diamine (D1) selected from 4,4′-diaminodiphenyl ether (ODA), p-phenylenediamine, (PDA).

7. A polyimide polymer, [polymer (PI)], obtainable from polymer (PAA) of anyone of claims 1 to 6.

8. A polyimide polymer (PI) comprising units derived from the polymerization of:
a component (AC) selected from 4,4′-oxydiphthalic anhydride (ODPA), 3,3′,4,4′-biphenyl tetracarboxylic dianhydride (BPDA),
20.0 to 80.0 mol %, even 25 to 80 mol % of a diamine (D) of formula (II), and
20.0 to 80.0 mol %, even 20 to 75 mol % of p-phenylenediamine, (PDA).

9. A composition comprising a polymer selected from the group consisting of a polymer (PAA) of anyone of claims 1 to 6 or a polymer (PI) of claim 7 or 8 and a polar organic solvent.

10. A photosensitive polymer composition comprising a polymer selected from the group consisting of a polymer (PAA) of anyone of claims 1 to 6 or a polymer (PI) of claim 7 or 8 and a photosensitive agent.

11. A pattern forming method, said method comprising:
a) applying a coating of the photosensitive polymer composition of claim 10 on a substrate;
b) masking the applied coating with a photomask having a pattern;
c) exposing the masked substrate obtained in step b) to a source of actinic radiation and developing the substrate; and
d) heat curing the developed substrate obtained in step c) to form a polyimide pattern.

12. The method of claim 11 wherein the photosensitive agent is selected from the group of o-quinone diazide compounds, azide compounds and diazo compounds.

13. The method of claim 11 wherein the photosensitive composition comprises a polymer selected from the group consisting of a polymer (PAA) of anyone of claims 1 to 6 and a polymer (PI) of claim 7 or 8 obtained by polymerizing a component (AC) of formula (V) wherein R₂ is a C₁-C₂₀ alkyl radical comprising at least one polymerizable group and wherein the photosensitive agent is selected from the group consisting of acylphosphine oxides, such as bis(2,4,6-trimethylbenzoyl)-phenylphosphineoxide, benzophenone and its derivatives, such as 4,4′-bis(dimethylamino)benzophenone, oximes and oxime esters, such as 1-phenylpropanedione-2-(o-methoxycarbonyl)oxime, 1-phenyl-3-ethoxy-propanetrione-2-(o-benzoyl)oxime; acetophenone derivatives, such as 2-hydroxy-2-methylpropiophenone, 2,2′-diethoxyacetophenone.

14. An article comprising at least one polymer selected from the group consisting of the polymer (PAA) of anyone of claims 1 to 6 and the polymer (PI) of claim 7 or 8.

15. A printed board of a semiconductor device or a microchip comprising at least one layer comprising a polymer (PAA) of anyone of claims 1 to 6 and/or a polymer (PI) of claim 7 or 8.
